(19) United States
(12) Patent Application Publication
(10) Pub. No.: US 2002/0106824 A1
(43) Pub. Date: Aug. 8, 2002

(54) Optical integrated circuit device, fabrication method of the same and module of optical communication transmission and receiving apparatus using the same

(76) Inventor: Ki Chul Shin, Kyunggi-do (KR)

Correspondence Address: ROTH & GOLDMAN, P.A., 523 W. 6TH STREET, SUITE 707, LOS ANGELES, CA, 90014, US

(21) Appl. No.: 10/004,342

(22) Filed: Nov. 21, 2001

(30) Foreign Application Priority Data
Nov. 23, 2000 (KR) 2000-69803

(51) Int. Cl. H01L 21/00

(52) U.S. Cl. 438/29; 438/98

(57) ABSTRACT

The present invention relates to an optical integrated circuit device, a fabrication method of the same and a module of an optical communication transmission and receiving apparatus using the same. The optical integrated circuit device comprises a semiconductor substrate, an active layer formed on an upper surface of the semiconductor substrate, a first current disconnection layer formed on an upper surface of the semiconductor substrate at both sides of the active later, a second current disconnection layer formed on an upper surface of the first current disconnection layer, and a convex portion formed on an upper portion of the active layer and an upper surface of the second current disconnection layer.

### BACKGROUND OF THE INVENTION

The present invention relates to an optical integrated circuit device, a fabrication method of the same and a module of an optical communication transmission and receiving apparatus using the same, and in particular to an optical integrated circuit device, a fabrication method of the same and a module of an optical communication transmission and receiving apparatus using the same which are capable of easily aligning the position of an optical integrated circuit device and optical fiber when assembling an optical communication transmission and receiving apparatus module, obtaining a short position aligning time and preventing a crack phenomenon at a corner portion of an optical integrated circuit device.

### DESCRIPTION OF THE BACKGROUND ART

Generally, In order to align a light source(an optical integrated circuit device like a laser diode chip and a photo diode chip) of an optical communication transmission and receiving apparatus module capable of converting an electrical signal into an optical signal or an optical signal into an electrical signal and an optical fiber, an active alignment method and a passive alignment method are used.

The active alignment method requires a long time for aligning a laser diode and an optical fiber for thereby decreasing a mass production. In addition, the active alignment method needs many parts, so that it is impossible to implement a low cost product.

Therefore, the passive alignment method in which a current is not applied to a laser diode, and a laser diode and an optical fiber are directly coupled is increasingly used.

FIG. 1A is a disassembled perspective view illustrating an optical communication transmission and receiving apparatus module for explaining a conventional active alignment method with respect to an optical integrated circuit device and an optical fiber.

As shown therein, the optical communication transmission and receiving apparatus module includes a mounting apparatus 100 for mounting an optical integrated circuit device, an optical fiber, etc. an optical fiber 110 installed in a V-shaped longitudinal groove 101 formed on an upper portion of the mounting apparatus 100, and an optical integrated circuit device(here, a laser diode) installed at an end portion of the optical fiber 110. At this time, a laser diode chip 120 is aligned and attached on an upper portion of the mounting apparatus 100 in such a manner that an active layer 121 which is a light emission layer of the laser diode chip 120 is positioned at the center of the optical fiber.

In order to implement an accurate alignment, a rotation adjusting mark 103, an optical axis adjusting mark 105, etc. are formed on an upper surface of the mounting apparatus 100. A position adjusting mark 123 is formed on the laser diode 120. FIG. 1A is a view of a method for checking whether the positions of the above marks are accurately aligned using an infrared ray camera. The optical fiber 110 and the active layer 121 of the laser diode chip 120 are matched in the above method.

FIG. 1B is a disassembled perspective view of a conventional communication transmission and receiving apparatus module for explaining another example of a position alignment method with respect to an optical integrated circuit device and an optical fiber.

As shown therein, a V-shaped groove 151 is formed on an upper surface of the mounting apparatus 150. An optical fiber 160 is installed on an upper portion of the V-shaped groove 151. A concave portion 152 is formed at an end of the V-shaped groove 151 for mounting the optical integrated circuit device 170 therein. A convex portion 171 corresponding to the concave portion 152 is formed on the surface of the optical integrated circuit device 170. The convex portion 171 of the optical integrated circuit device 170 is inserted into the concave portion 152 of the mounting apparatus 150, so that the optical fiber 160 and the active layer 172 of the optical integrate circuit device 170 are matched.

However, the above-described conventional position alignment method has the following disadvantages.

The method of FIG. 1A has an advantage in that the number of parts is decreased for aligning the optical integrated circuit device and the optical fiber. However, since an expensive flip chip bonder which requires an accurate resolution is used, the installation cost of the equipment is high. In addition, the above method is not better than an active alignment method in a view of the process time. The method of FIG. 1B will be explained with reference to FIGS. 2A and 2B. FIGS. 2A and 2B are vertical cross-sectional views taken along line IIa-IIa after mounting the optical integrated circuit device 170 of FIG. 1B on the mounting apparatus 150.

FIG. 2A is a view illustrating a convex portion 171 formed on an upper surface of the conventional optical integrated circuit device 170 in which a lateral surface 172a has a vertical profile. FIG. 2B is a view illustrating a convex portion of the conventional optical integrated circuit device 170 in which a lateral surface 172b has a reverse taper.

As shown in FIGS. 2A and 2B, the size L1 of the concave portion of the mounting apparatus 150 is larger than the size L2 of the convex portion 171 of the optical integrated circuit device 170. Therefore, as shown in FIGS. 2A and 2B, the convex portion 171 is inserted into the convex portion 152 of the mounting apparatus 150. The optical integrated circuit device 150 is horizontally moved so that the lateral surfaces 152a and 152b of the concave portion 152 and the lateral surfaces 171a and 171b of the convex portion 171 closely contact each other.

At this time, in the case of the convex portion 171 having a nearly perpendicular lateral wall profile, when inserting the convex portion 171 into the concave portion 152, an end portion A of the convex 171 collides with an upper portion of the mounting apparatus 150, so that the end portion A of the same may be cracked.

In the case that the convex portion 171 having a reverse taper lateral wall profile, an end portion B of the convex portion 171 may collide with a lateral wall of the concave portion 150 of the mounting apparatus, so that the end portion B of the same is cracked. Therefore, a certain defect may occur in the optical integrated circuit device due to the cracks. In addition, a matching property of an alignment between the optical fiber and the optical integrated circuit device may be decreased due to the reverse taper lateral wall profile.

### SUMMARY OF THE INVENTION

Accordingly, it is an object of the present invention to provide an optical integrated circuit device and a fabrication method of the same which are capable of easily aligning the position of an optical integrated circuit device and optical fiber when assembling an optical communication transmission and receiving apparatus module, obtaining a short position aligning time and preventing a crack phenomenon at a corner portion of an optical integrated circuit device.

To achieve the above objects, there is provided an optical integrated circuit device, comprising a semiconductor substrate, an active layer formed on an upper surface of the semiconductor substrate, a first current disconnection layer formed on an upper surface of the semiconductor substrate at both sides of the active later, a second current disconnection layer formed on an upper surface of the first current disconnection layer, and a convex portion formed on an upper portion of the active layer and an upper surface of the second current disconnection layer.

The convex portion is a taper shaped profile at both sides of the same.

A slant of both sides of the convex portion is 10˜70° with respect to an axis perpendicular to the upper surface of the semiconductor substrate.

The convex portion is a trapezoid. The convex portion is a clad layer.

There is further provided a protection later formed on an upper surface of the second current disconnection layer and an upper surface of both side surfaces of the convex portion.

There are further provided a first electrode formed on an upper surface of the convex portion between the protection layers, and a second electrode formed on a lower surface of the semiconductor substrate.

The protection layer is a silicon oxide film or a silicon nitride film.

To achieve the above object, there is provided an optical integrated circuit device fabrication method, comprising a step for forming an active layer on an upper surface of a semiconductor substrate using a MOCVD method, a step for forming a first current disconnection layer on an upper surface of the semiconductor substrate a both sides of the active layer using the MOCVD method, a step for selectively growing a second current disconnection later on an upper surface of the first current disconnection layer, a step for forming a convex portion having a taper shaped lateral surface on a part of an upper portion of the active layer and a part of an upper surface of the second current disconnection layer, a step for forming a protection film on a lateral surface of the convex portion and an upper surface of the second current disconnection layer, a step for forming a first electrode on an upper surface of the convex portion, and a step for forming a second electrode on a lower surface of the semiconductor substrate.

The convex portion formation step includes a step for selectively growing a clad layer on an upper surface of the second current disconnection layer and an upper portion of the active layer by the MOCVD method, a step for forming a photoresist pattern on an upper surface of the clad layer and an upper portion of the active layer, and a step for isotropically etching the clad layer using the photoresist pattern as an etching mask.

The size of the photoresist pattern is larger than the active layer.

The size of the photoresist pattern is 75 μm in length in both directions from the center of the active layer.

The protection film is a silicon oxide film or a silicon nitride film.

The step for forming a convex portion on an upper portion of the active layer includes a step for forming a mask layer on a part of an upper surface of the second current disconnection layer, a step for forming a clad layer using a selective MOCVD growing method on an upper surface of the second current disconnection layer and an upper portion of the active layer on which the mask layer is not covered, and a step for removing the mask layer.

To achieve the above object, there is provided an optical communication transmission and receiving apparatus module, comprising an optical integrated circuit device including a semiconductor substrate, an active layer formed on an upper surface of the semiconductor substrate, a first current disconnection layer formed on an upper surface of the semiconductor substrate at both sides of the active layer, a second current disconnection layer formed on an upper surface of the first current disconnection layer, a convex portion formed on an upper portion of the active layer and an upper surface of the second current disconnection layer and having a taper shape at a lateral surface of the same, a protection film formed on a lateral surface of the convex portion and an upper surface of the second current disconnection layer, a first electrode formed on an upper surface of the convex portion, and a second electrode formed on a lower surface of the semiconductor substrate, a mounting apparatus having a concave portion having a reverse taper shaped lateral wall profile at the upper center portion, a third electrode having a part embedded in the mounting apparatus and another part extended on a lower surface of the concave portion and a fourth electrode formed on an edge upper surface of the mounting apparatus, wherein the third electrode formed on a lower surface of the concave portion of the mounting apparatus and a first electrode of the optical integrated circuit device contact each other.

There is further provided a conductive wire for connecting the second electrode and the fourth electrode.

The positions of the optical fiber and the optical integrated circuit device are automatically aligned by inserting the convex portion of the optical integrated circuit device into the concave portion of the mounting apparatus.

The position of the optical fiber and the optical integrated circuit device is automatically aligned by performing a step in which the convex portion of the optical integrated circuit device is inserted into the concave portion of the mounting apparatus and a step in which the optical integrated circuit device is horizontally moved, so that the protection film formed at the lateral wall of the convex portion contacts with one lateral wall of the concave portion.

### BRIEF DESCRIPTION OF THE DRAWINGS

The present invention will become better understood with reference to the accompanying drawings which are given only by way of illustration and thus are not limitative of the present invention, wherein:

FIG. 1A and 1B are disassembled respective views illustrating a conventional optical communication transmission and receiving apparatus module and a conventional method for manually aligning an optical integrated circuit device(laser diode chip) and an optical fiber;

FIGS. 2A and 2B are cross-sectional views illustrating a conventional optical communication transmission and receiving apparatus module and a state that an optical integrated circuit device(laser diode chip) is manually aligned on an optical fiber and is mounted on a mounting apparatus;

FIG. 3 is a cross-sectional view illustrating an optical integrated circuit device according to the present invention;

FIG. 4 is a cross-sectional view illustrating an optical communication transmission and receiving apparatus module and a state that an optical integrated circuit device is manually aligned on an optical fiber according to the present invention;

FIGS. 5A through 5G re cross-sectional views illustrating a fabrication method of an optical integrated circuit device based on a fabrication sequence of an optical integrated circuit device according to an embodiment of the present invention; and

FIGS. 6A through 6E are cross-sectional views illustrating a method for fabricating an optical integrated circuit device based on a fabrication sequence of an optical integrated circuit device according to another embodiment of the present invention.

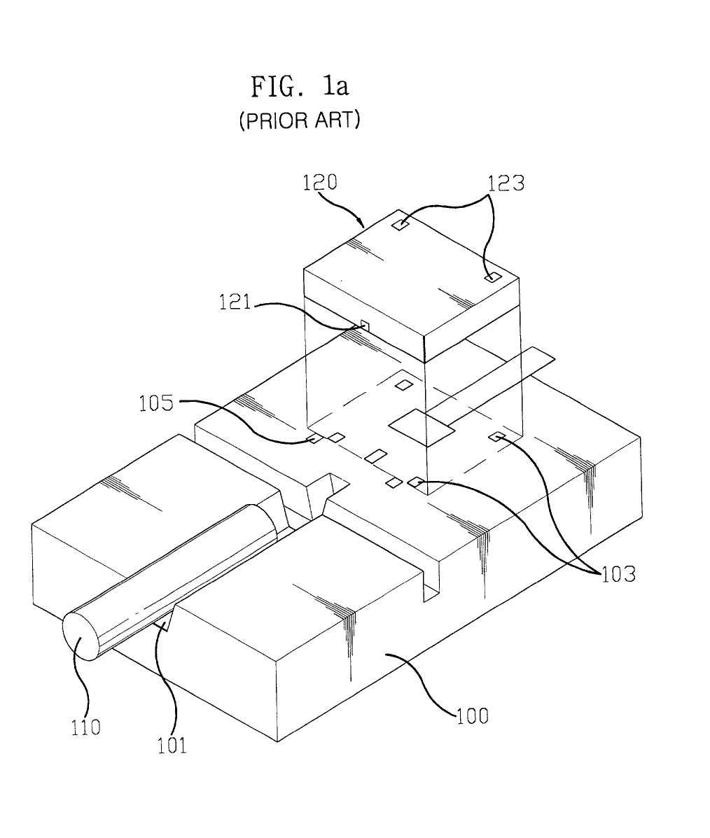

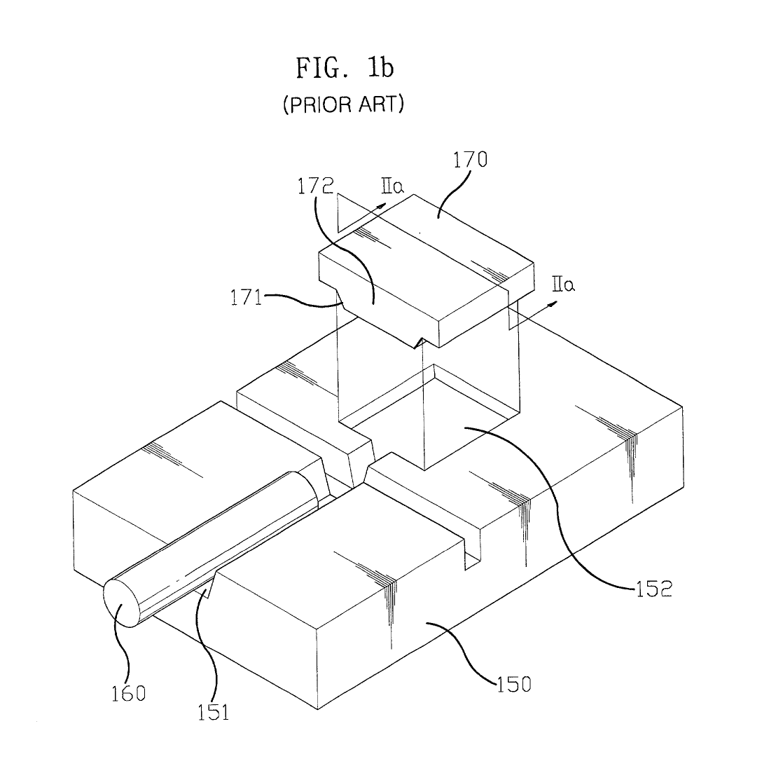

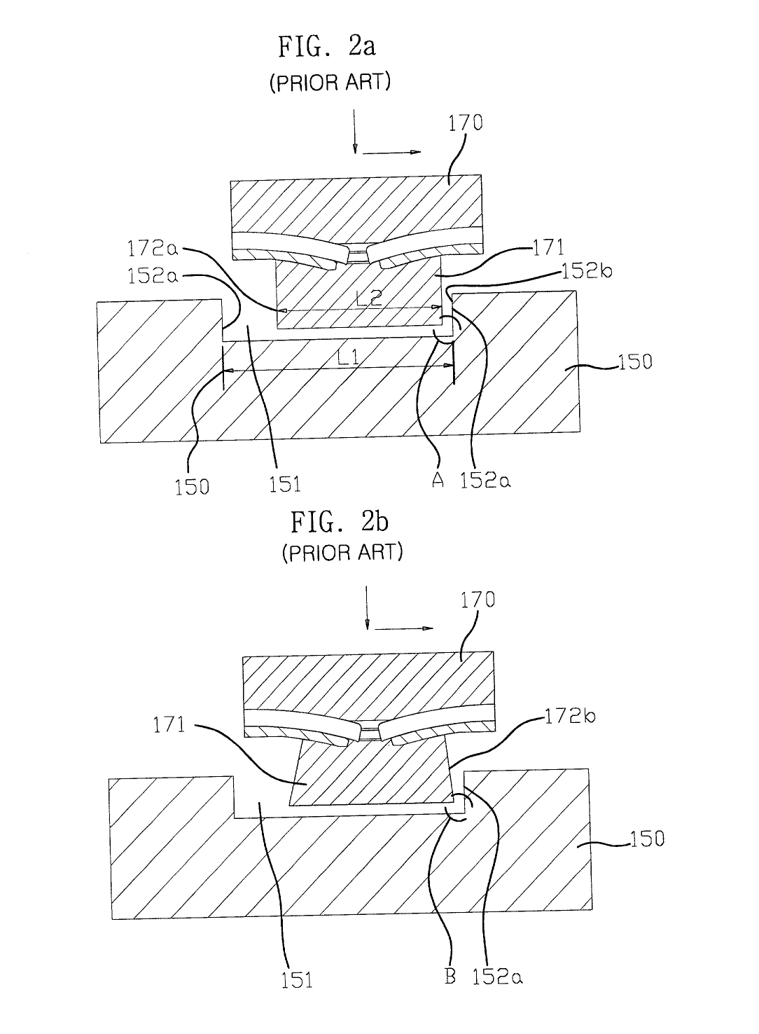

### DETAILED DESCRIPTION OF THE PREFERRED EMBODIMENTS

The embodiments of the present invention will be explained with reference to the accompanying drawings.

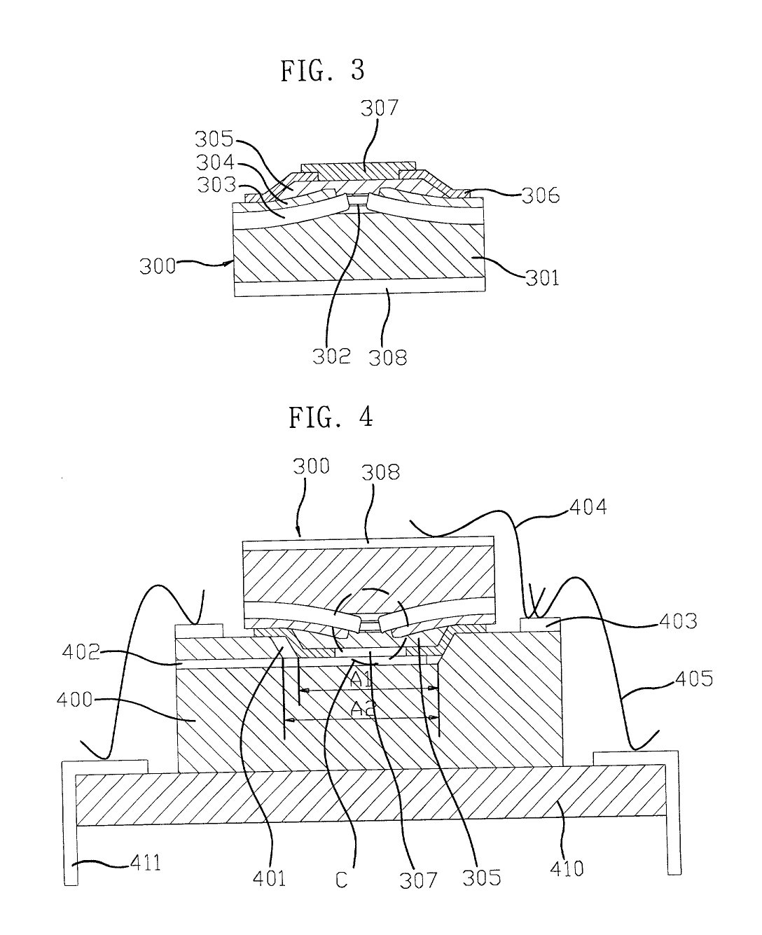

FIG. 3 is a cross-sectional view illustrating an optical integrated circuit device according to the present invention. An optical integrated circuit device 300 which is adapted as an embodiment of the present invention is an optical communication laser diode chip.

As shown therein, the optical integrated circuit device 300 includes an InP substrate 301 of a p-type or n-type which is a base substrate, an active layer 302 formed on an upper center portion of the base substrate 301, a first current disconnection layer 303 formed on an upper surface of the base substrate 301 at both sides of the active layer 302, a second current disconnection layer 304 formed on an upper surface of the first current disconnection layer 303, a clad layer 305 formed on the upper portions of the second current disconnection layer 304 and the active layer 302 and having a taper-shaped lateral profile, a protection film 306 covering a part of an upper edge portion of the clad layer 305 and an upper surface of the second current disconnection layer 303, a first electrode 307 formed on an upper surface of the clad layer 305 and a second electrode 308 formed on a lower surface of the base electrode 301.

In the optical integrated circuit device according to the present invention, the clad layer 305 includes a taper-shaped profile at both sides of the same. The clad layer 305 operates a position alignment mask function for aligning the position at the mounting apparatus when fabricating an optical communication transmission and receiving module. Hereinafter, the clad layer 305 is called as a convex portion. The clad layer 305, namely, the convex portion 305 is fabricated in a trapezoid shape having a taper shaped lateral wall profile. In addition, the lateral wall profile of the convex portion 305 has a slanted angle of about 10˜70° from a vertical direction to the lateral wall with respect to the surface of the base substrate 301.

In addition, an edge corner portion of the clad layer 305 which is the convex portion is covered by the protection film 306. The material of the protection film 306 is preferably a silicon oxide film (SiO₂) or a silicon nitride film (SiNₓ).

FIG. 4 is a cross-sectional view illustrating an optical communication transmission and receiving apparatus module fabricated using an optical integrated circuit device of FIG. 3 according to the present invention.

As shown in FIG. 4, the optical integrated circuit device 300 of FIG. 3 is mounted on an upper surface of the mounting apparatus(SiOB: silicon Optical Bench).

The optical communication transmission and receiving module includes a mounting apparatus 400 having a concave portion 402 at an upper center portion, and an optical integrated circuit device 300 mounted on the concave portion 401. The size A1 of the concave portion 401 is larger than the size A2 of the convex portion 310 by about 1 μm. The lateral wall profile of the concave portion 401 is formed in a reverse taper shape.

A third electrode 402 electrically connected with the first electrode 306 of the optical integrated circuit device is embedded in the mounting apparatus 400. The third electrode 402 is extended to an upper surface of the concave portion 401.

The first electrode 307 of the optical integrated circuit device 300 contacts with the third electrode 402 formed on an upper surface of the concave portion 401.

A fourth electrode 403 is formed on an upper edge portion of the mounting apparatus 400 for connecting with the second electrode 308 of the optical integrated circuit device 300. The second electrode 307 and the fourth electrode 403 are electrically connected by a first conductive wire 404.

A support plate 400 is installed on a lower surface of the mounting apparatus 400. A reversed L-shaped outer lead 411 is installed at both edge portions of the support plate 410. The outer lead 411 and the fourth electrode 403 are connected with a second conductive wire 405.

As shown in FIG. 4, in the optical communication transmission and receiving module according to the present invention, the circle C indicated by the dotted line represents the position of the optical fiber.

As shown in FIG. 4, in the optical communication transmission and receiving module according to the present invention, the convex portion 305 of the optical integrated circuit device 300 is inserted into the concave portion 401 of the mounting apparatus 400, so that it is possible to automatically align the position of the optical fiber and the optical integrated circuit device 300. In addition, the convex portion 305 and the concave portion 401 each include a taper shaped lateral wall and a reverse taper shaped lateral wall, so that when the optical integrated circuit device is inserted into the mounting apparatus, an edge portion of the optical integrated circuit device is not cracked. In addition, the protection film 306 which covers the convex portion 305 of the optical integrated circuit device prevents the optical integrated circuit device from being physically damaged when the optical integrated circuit device is inserted into the mounting apparatus and helps a smooth insertion of the convex portion 305 when the convex portion 305 is inserted into the concave portion 401. In addition, the protection film prevents other portions from being contacted with unnecessary portions except for that the optical circuit device and the mounting apparatus contact with the electrodes for thereby enhancing an electrical reliability of the optical communication transmission and receiving module.

In addition, the module of FIG. 4 is installed in such a manner that the protection film 306 formed at the lateral wall of the convex portion of the optical integrated circuit device and the lateral wall 401a of the concave portion 401 do not contact each other, so that the position alignment of the optical fiber and the optical integrated circuit device is implemented.

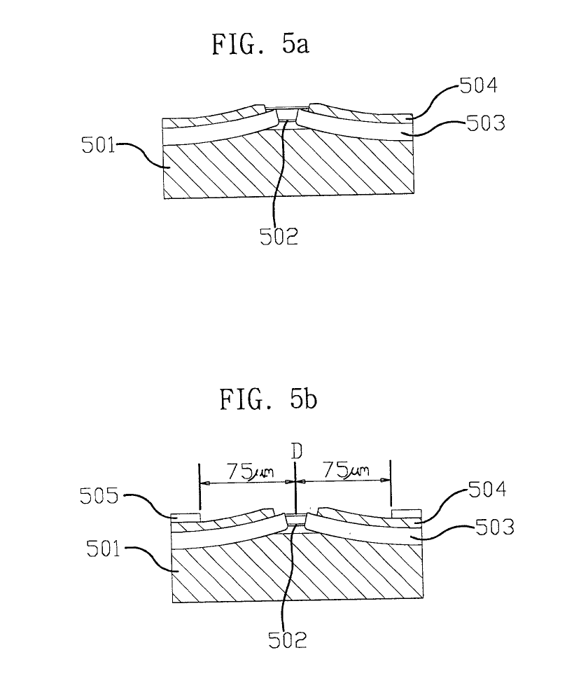

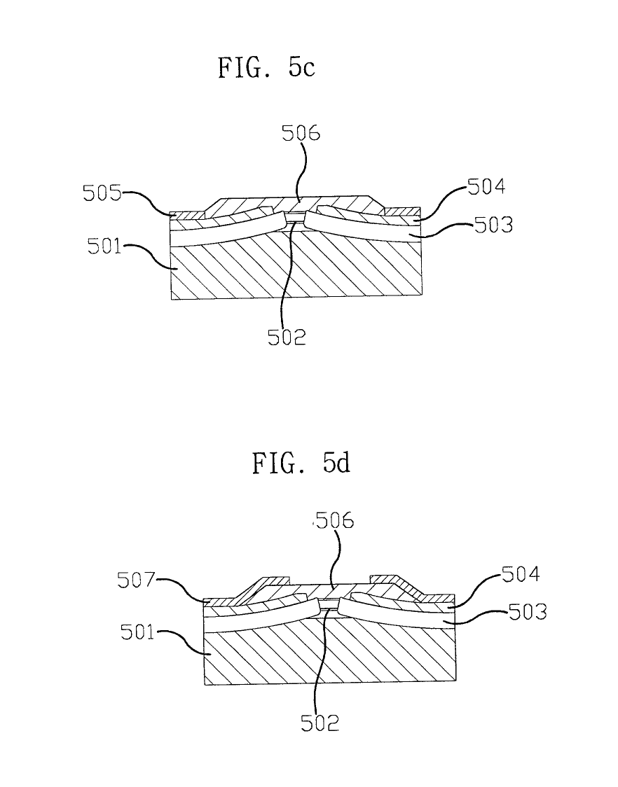

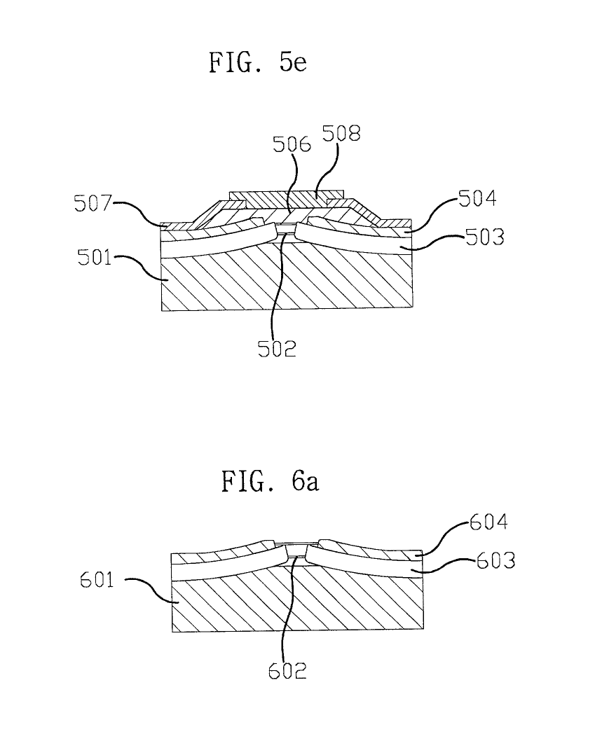

As shown in FIG. 5a, an active layer 502, a first current disconnection layer 503 and a second current disconnection layer 504 are selectively grown on an upper surface of the n-InP or p-InP semiconductor substrate 501 by a known MOCVD method.

As shown in FIG. 5B, a silicon oxide film or a silicon nitride film is formed on an upper surface of the second current disconnection layer 504. The oxide film or silicon nitride film formed on the upper surface of the second current disconnection layer 504 are removed from the portion which is distanced from the upper portion of the active layer 502 and the center D of the active layer by 75 μm for thereby forming a mask layer 505 on a part of the upper surface of the second current disconnection layer 504. Namely, the material of the mask layer 505 is a silicon oxide film or silicon nitride film.

As shown in FIG. 5C, the clad layer 506 is selectively grown on the upper surface of the second current disconnection layer 504 except for the mask layer 505 by the MOCVD method. At this time, the clad layer 505 has a taper shape of the lateral profile.

As shown in FIG. 5D, the mask layer 504 is removed, and a silicon oxide film or a silicon nitride film which is the protection layer 507 is formed on the upper surfaces of the clad layer 505 and the second current disconnection layer 504 and then are patterned. A part of the clad layer 505 of the active layer 502 is exposed.

As shown in FIG. 5E, a first electrode 508 is formed on an upper surface of the clad layer 506.

A second electrode 509 is formed on a lower surface of the base substrate 501 for thereby completing a fabrication of the optical integrated circuit device according to the present invention.

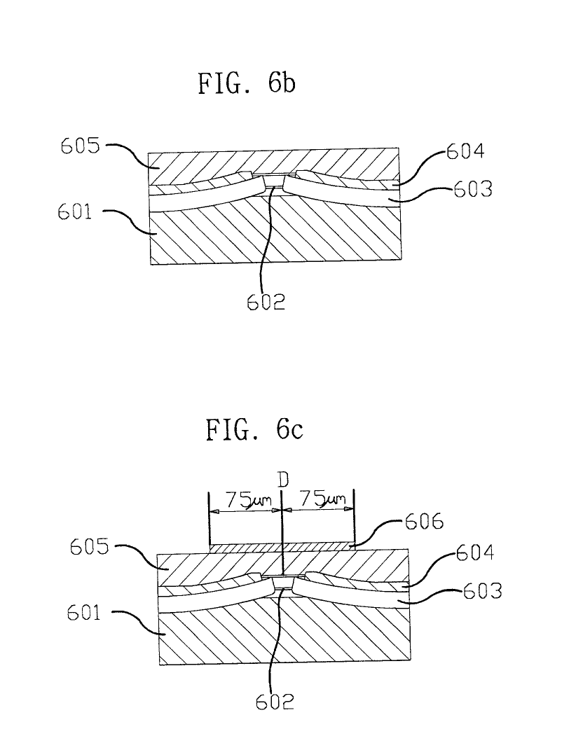

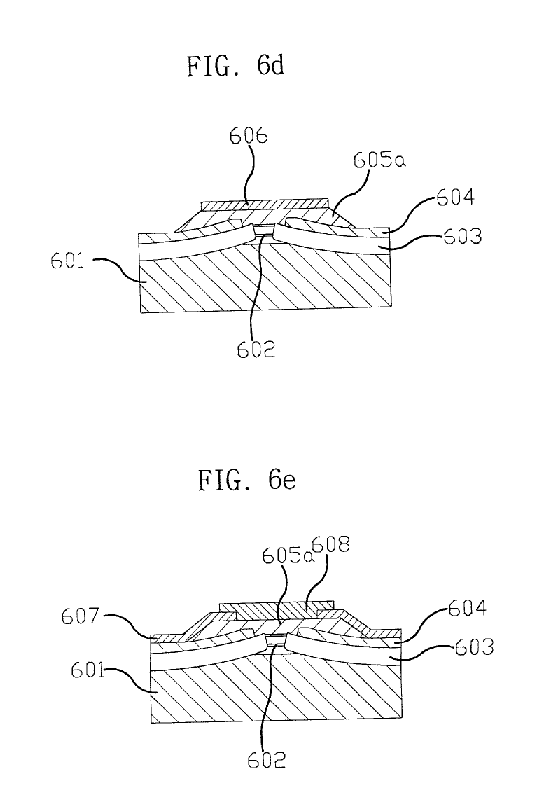

The optical integrated circuit device according to the present invention may be fabricated by another embodiment of the present invention. The another embodiment of the present invention will be explained with reference to FIGS. 6A through 6E.

As shown in FIG. 6A, an active layer 602, a first current disconnection layer 603 and a second current disconnection layer 604 are formed on an upper surface of a n-InP or p-InP semiconductor substrate 601 by a known MOCVD method.

Next, as shown in FIG. 6B, a clad layer 605 is formed on the upper portion of the active layer 602 and the upper surface of the second current disconnection layer 604.

As shown in FIG. 6C, a photoresist pattern 606 is formed on an upper surface of the clad layer 605. The photoresist pattern 606 is formed on an upper portion of the active layer and has a size of about 75 μm in both directions from the center of the active layer.

The clad layer pattern 605a is formed by etching the clad layer 605 using the photoresist pattern 606 as an etching mask by a chemical etching method as shown in FIG. 6D. The chemical etching method is an isotrophy etching method. In this case, the under cut phenomenon occurs during the etching process. Therefore, the profiles of both sides of the clad layer pattern 605a has a taper shape.

As shown in FIG. 6E, a protection film 607 is formed at both sides of the clad layer pattern 605a and on an upper surface of the second current disconnection layer 604. A first electrode 608 is formed on an upper surface of the clad layer pattern 605a of the active layer 602. A second electrode 609 is formed on a lower surface of the base substrate 601 for thereby completing a fabrication of the optical integrated circuit device according to the present invention.

When fabricating the clad layer pattern 605a, namely, the convex portion using the chemical etching method as shown in FIGS. 6A through 6E, the size of the clad layer pattern 605a is adjustable within ±0.5 μm. Therefore, it is possible to fabricate the convex portion having an accurate size. Therefore, the convex portion is inserted into the concave portion having a size corresponding to the size of the convex portion, namely, the clad layer pattern 605a, so that it is possible to quickly align the optical integrated circuit device and the optical fiber(automatic passive alignment).

In the above embodiment of the present invention, a laser diode chip was adapted to explain the present invention. The photo diode chip may be adapted for the same purpose as the laser diode chip.

In the present invention, when aligning the optical integrated circuit device of the optical communication transmission and receiving apparatus module and the optical fiber, a protruded shape laser diode chip is used for easily adjusting the position during the alignment, so that it is possible to quicldy and simply perform a manual alignment of the optical integrated circuit device and the optical fiber.

In addition, in the present invention, an expensive flip chip bonder which requires an accurate resolution is not needed. In the present invention, a few thousands optical integrated circuit devices are die-bonded at one time, so that it is possible to significantly decrease the time required for the alignment of the optical integrated circuit device and the optical fiber, and the price of the optical communication transmission and receiving apparatus module is largely decreased.

When mounting the integrated circuit device into the concave portion of the mounting apparatus, it is possible to prevent the convex portion of the optical integrated circuit device from being cracked by forming a protection film at a corner potion of the convex portion of the optical integrated circuit device, so that an error occurrence of the product is decreased.

The convex portion of the optical integrated circuit device is smoothly inserted into the concave portion of the mounting apparatus when assembling the optical integrated circuit device to the optical communication transmission and receiving module by forming the protection film for thereby implementing an easier assembling operation of the module.

In the present invention, a wire bonding process is not needed when mounting on the mounting apparatus of the optical communication apparatus module by forming all electrodes of the optical integrated circuit on the upper portion of the semiconductor substrate, so that the assembling cost of the optical communication apparatus module is decreased, and the assembling operation is easily obtained, and the assembling time is decreased.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

1. An optical integrated circuit device, comprising:
a semiconductor substrate;
an active layer formed on an upper surface of the semiconductor substrate;
a first current disconnection layer formed on an upper surface of the semiconductor substrate at both sides of the active later;
a second current disconnection layer formed on an upper surface of the first current disconnection layer; and
a convex portion formed on an upper portion of the active layer and an upper surface of the second current disconnection layer.

2.The device of claim 1, wherein said convex portion is a taper shaped profile at both sides of the same.

3. The device of claim 2, wherein a slant of both sides of the convex portion is 10˜70° with respect to an axis perpendicular to the upper surface of the semiconductor substrate.

4. The device of claim 1, wherein said convex portion is a trapezoid.

5. The device of claim 1, wherein said convex portion is a clad layer.

6. The device of claim 1, further comprising a protection later formed on an upper surface of the second current disconnection layer and an upper surface of both side surfaces of the convex portion.

7. The device of claim 6, further comprising a first electrode formed on an upper surface of the convex portion between the protection layers, and a second electrode formed on a lower surface of the semiconductor substrate.

8. The device of claim 6, wherein said protection layer is a silicon oxide film or a silicon nitride film.

9. An optical integrated circuit device fabrication method, comprising:
a step for forming an active layer on an upper surface of a semiconductor substrate using a MOCVD method;
a step for forming a first current disconnection layer on an upper surface of the semiconductor substrate a both sides of the active layer using the MOCVD method;
a step for selectively growing a second current disconnection later on an upper surface of the first current disconnection layer;
a step for forming a convex portion having a taper shaped lateral surface on a part of an upper portion of the active layer and a part of an upper surface of the second current disconnection layer;
a step for forming a protection film on a lateral surface of the convex portion and an upper surface of the second current disconnection layer;
a step for forming a first electrode on an upper surface of the convex portion; and
a step for forming a second electrode on a lower surface of the semiconductor substrate.

10. The method of claim 9, wherein said convex portion formation step includes:
a step for selectively growing a clad layer on an upper surface of the second current disconnection layer and an upper portion of the active layer by the MOCVD method;
a step for forming a photoresist pattern on an upper surface of the clad layer and an upper portion of the active layer; and
a step for isotropically etching the clad layer using the photoresist pattern as an etching mask.

11. The method of claim 10, wherein the size of the photoresist pattern is larger than the active layer.

12. The method of claim 11, wherein the size of the photoresist pattern is 75 μm in length in both directions from the center of the active layer.

13. The method of claim 9, wherein said protection film is a silicon oxide film or a silicon nitride film.

14. The method of claim 9, wherein said step for forming a convex portion on an upper portion of the active layer includes:
a step for forming a mask layer on a part of an upper surface of the second current disconnection layer;
a step for forming a clad layer using a selective MOCVD growing method on an upper surface of the second current disconnection layer and an upper portion of the active layer on which the mask layer is not covered; and
a step for removing the mask layer.

15. An optical communication transmission and receiving apparatus module, comprising:
an optical integrated circuit device including:
a semiconductor substrate;
an active layer formed on an upper surface of the semiconductor substrate;
a first current disconnection layer formed on an upper surface of the semiconductor substrate at both sides of the active layer;
a second current disconnection layer formed on an upper surface of the first current disconnection layer;
a convex portion formed on an upper portion of the active layer and an upper surface of the second current disconnection layer and having a taper shape at a lateral surface of the same;
a protection film formed on a lateral surface of the convex portion and an upper surface of the second current disconnection layer;
a first electrode formed on an upper surface of the convex portion; and
a second electrode formed on a lower surface of the semiconductor substrate;
a mounting apparatus having a concave portion having a reverse taper shaped lateral wall profile at the upper center portion;
a third electrode having a part embedded in the mounting apparatus and another part extended on a lower surface of the concave portion and
a fourth electrode formed on an edge upper surface of the mounting apparatus, wherein said third electrode formed on a lower surface of the concave portion of the mounting apparatus and a first electrode of the optical integrated circuit device contact each other.

16. The module of claim 15, further comprising a conductive wire for connecting the second electrode and the fourth electrode.

17. The module of claim 15, wherein the positions of the optical fiber and the optical integrated circuit device are automatically aligned by inserting the convex portion of the optical integrated circuit device into the concave portion of the mounting apparatus.

18. The module of claim 15, wherein the position of the optical fiber and the optical integrated circuit device is automatically aligned by performing a step in which the convex portion of the optical integrated circuit device is inserted into the concave portion of the mounting apparatus and a step in which the optical integrated circuit device is horizontally moved, so that the protection film formed at the lateral wall of the convex portion contacts with one lateral wall of the concave portion
